(19) United States
(12) Patent Application Publication
(10) Pub. No.: US 2007/0039716 A1
(43) Pub. Date: Feb. 22, 2007

(54) Heat dissipating unit

(75) Inventors: Cheng-Tang Yeh, Jen Te Hsiang (TW); Jen-Lu Hu, Tainan City (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: MAN ZAI INDUSTRIAL CO., LTD., Tainan City (TW)

(21) Appl. No.: 11/312,152

(22) Filed: Dec. 19, 2005

(30) Foreign Application Priority Data
Aug. 17, 2005 (TW) 094214073

(51) Int. Cl. H05K 7/20

(52) U.S. Cl. 165/80.4; 165/170; 361/699

(57) ABSTRACT

A heat dissipating unit includes: a housing defining an inner space therein, a fluid inlet in fluid communication with the inner space and adapted to receive a coolant therein, and a fluid outlet in fluid communication with the inner space and adapted to discharge the coolant therefrom; a plurality of partitioning plates disposed in the inner space so as to divide the inner space into a plurality of compartments that are connected to each other in an end-to-end manner such that the compartments cooperate to form a continuous tortuous channel with two ends respectively connected to the fluid inlet and the fluid outlet; and a plurality of heat dissipating fins that are formed in each of the compartments.

### BACKGROUND OF THE INVENTION

1. Field of the Invention

The invention relates to a heat dissipating unit, more particularly to a heat dissipating unit for a central processing unit (CPU).

2. Description of the Related Art

As shown in FIG. 1, a conventional coolant-filled heat dissipating unit 1 suitable for use as a heat sink for a central processing unit (CPU) 10, generally includes a rectangular housing 11 made from a heat-conductive material, and a cover plate 13 sealingly mounted on the housing 11 through a plurality of fasteners 12. The housing 11 includes an abutment face 111 abutting against a surface of the central processing unit 10, and a cover mounting face 112 opposite to the abutment face 111, confronting the cover plate 13, and formed with a tortuous coolant channel 113. The coolant channel 113 has a coolant inlet end 114 and a coolant outlet end 115. The cover plate 13 is formed with a coolant inlet 131 aligned with the coolant inlet end 114, and a coolant outlet 132 aligned with the coolant outlet end 115. Each of the coolant inlet 131 and the coolant outlet 132 is connected to a corresponding coolant conduit of a coolant circulating device for circulation of the coolant through the coolant outlet 132 and the coolant inlet 131. Since the design of this invention is not related to the coolant circulating device, functional and structural details of the coolant cooling device will not be described herein.

In operation, the conventional heat dissipating unit 1 absorbs heat from the central processing unit 10 through the abutment face 11 of the housing 11, and then dissipates the heat through the coolant passing through the coolant channel 113. Although the aforesaid heat dissipating unit can dissipate heat from the CPU 10, the contact area between the abutment surface 111 of the housing 11 and the coolant is relatively small, and the heat dissipating efficiency thereof is relatively poor.

### SUMMARY OF THE INVENTION

Therefore, the object of the present invention is to provide a heat dissipating unit that can overcome the aforesaid drawback associated with the prior art.

According to one aspect of the present invention, there is provided a heat dissipating unit that comprises: a housing defining an inner space therein, a fluid inlet in fluid communication with the inner space and adapted to receive a coolant therein, and a fluid outlet in fluid communication with the inner space and adapted to discharge the coolant therefrom; a plurality of partitioning plates disposed in the inner space so as to divide the inner space into a plurality of compartments that are connected to each other in an end-to-end manner such that the compartments cooperate to form a continuous tortuous channel with two ends respectively connected to the fluid inlet and the fluid outlet; and a plurality of heat dissipating fins that are formed in each of the compartments.

According to another aspect of the present invention, there is provided a central processing unit (CPU) cooling device that comprises: a housing defining an inner space therein, a fluid inlet in fluid communication with the inner space and adapted to receive a coolant therein, and a fluid outlet in fluid communication with the inner space and adapted to discharge the coolant therefrom, the housing having a lower wall with a planar outer surface; a plurality of partitioning plates disposed in the inner space so as to divide the inner space into a plurality of compartments that are connected to each other in an end-to-end manner such that the compartments cooperate to form a continuous tortuous channel with two ends respectively connected to the fluid inlet and the fluid outlet; a thermally conductive pad bonded to the planar outer surface of the lower wall of the housing and adapted to be bonded to a central processing unit for conducting heat from the central processing unit to the coolant in the tortuous channel; and a plurality of heat dissipating fins that are formed in each of the compartments.

### BRIEF DESCRIPTION OF THE DRAWINGS

Other features and advantages of the present invention will become apparent in the following detailed description of the preferred embodiment with reference to the accompanying drawings, of which:

FIG. 1 is an exploded perspective view of a conventional heat dissipating unit for a central processing unit;

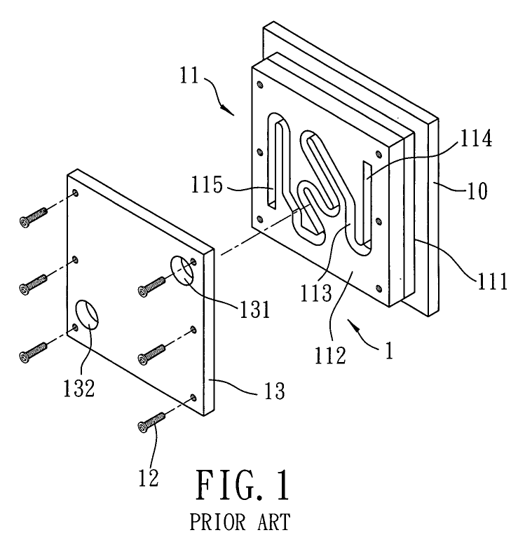

FIG. 2 is an exploded perspective view of the preferred embodiment of a central processing unit cooling device according to the present invention;

FIG. 3 is an exploded partly sectional view of the preferred embodiment; and

FIG. 4 is a schematic view of the preferred embodiment.

### DETAILED DESCRIPTION OF THE PREFERRED EMBODIMENT

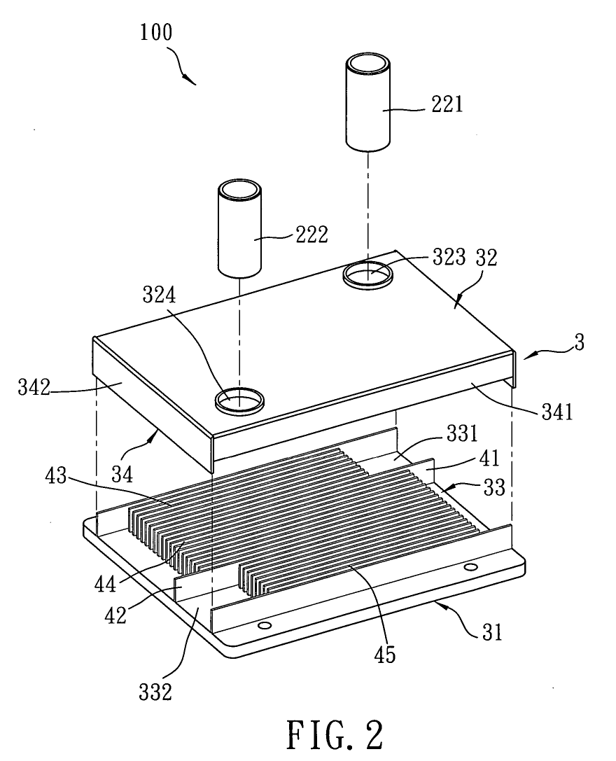

Referring to FIGS. 2 to 4, the preferred embodiment of a cooling device according to the present invention is shown to be adapted for use as a heat sink for a central processing unit (CPU) 21 so as to dissipate heat generated by the latter.

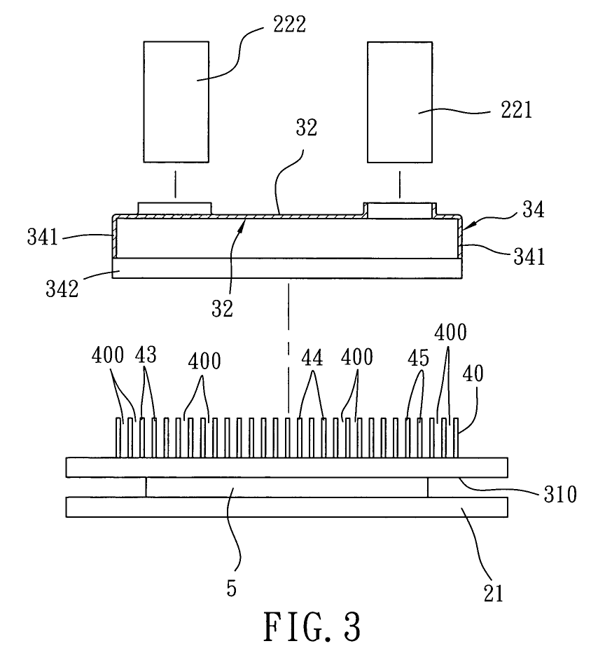

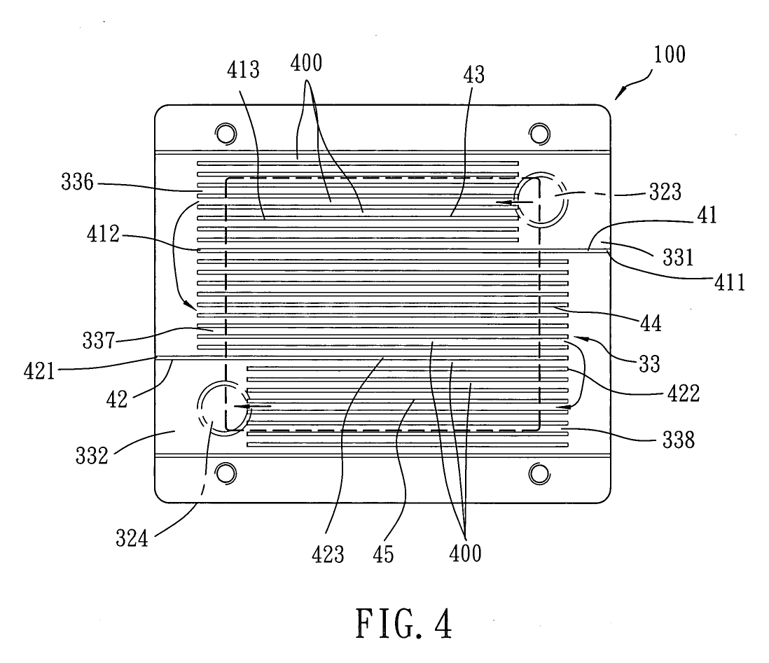

The CPU cooling device includes a heat dissipating unit 100 and a thermally conductive pad 5 (see FIG. 3). The heat dissipating unit 100 includes: a housing 3 defining an inner space 33 therein, a fluid inlet 323 in fluid communication with the inner space 33 and adapted to receive a coolant therein, and a fluid outlet 324 in fluid communication with the inner space 33 and adapted to discharge the coolant therefrom, the housing 3 having a lower wall 31 with a planar outer surface 310; a plurality of partitioning plates 41, 42 disposed in the inner space 33 so as to divide the inner space 33 into a plurality of compartments 336, 337, 338 (see FIG. 4) that are connected to each other in an end-to-end manner such that the compartments 336, 337, 338 cooperate to form a continuous tortuous channel with two ends 331, 332 respectively connected to the fluid inlet 323 and the fluid outlet 324; and a plurality of heat dissipating fins 43, 44, 45 that are formed in each of the compartments 336, 337, 338. The thermally conductive pad 5 is bonded to the planar outer surface 310 of the lower wall 31 of the housing 3, and a top surface of the central processing unit 21 for conducting heat from the central processing unit 21 to the coolant in the tortuous channel in the housing 3.

The fluid inlet 323 and the fluid outlet 324 are respectively connected to two coolant conduits 221, 222 of a coolant circulating device (not shown).

The housing 3 is made from a metal material, and further has an upper wall 32 opposite to the lower wall 31. The fluid inlet 323 and the fluid outlet 324 are formed in the upper wall 32. Each of the partitioning plates 41, 42 is transverse to and interconnects the upper and lower walls 31, 32. Each of the heat dissipating fins 43, 44, 45 is transverse to and interconnects the upper and lower walls 31, 32. Each of the compartments 43, 44, 45 is divided into a plurality of fluid passages 400 (see FIG. 3) by the respective ones of the heat dissipating fins 43, 44, 45. In this embodiment, each of the heat dissipating fins 43, 44, 45 is in the form of a thin plate.

Moreover, the housing 3 further has a surrounding wall 34 transverse to and interconnecting the upper and lower walls 31, 32, and having two parallel first side wall portions 341, and two parallel second side wall portions 342 interconnecting the first side wall portions 341. The partitioning plates 41, 42 and the heat dissipating fins 43, 44, 45 are parallel to the first side wall portions 341. Each of the partitioning plates 41, 42 extends from a respective one of the second side wall portions 342 toward the other of the second side wall portions 342, and has a connecting end 411, 421 and a free end 412, 422 opposite to the connecting end 411, 421. The connecting ends 411, 421 of each two adjacent ones of the partitioning plates 41, 42 are respectively connected to the second side wall portions 342 of the surrounding wall 34 of the housing 3. Referring to FIG. 4, each of the partitioning plates 41, 42 further has a free end section 413, 423 that extends from the free end 412, 422 toward the connecting end 411, 421. The free end sections 413, 423 of each two adjacent ones of the partitioning plates 41, 42 are disposed to overlap each other. The heat dissipating fins 43 are disposed between the surrounding wall 34 and the partitioning plate 41. The heat dissipating fins 44 are disposed between the free end sections 411, 432 of the adjacent ones of the partitioning plates 41, 42. The heat dissipating fins 45 are disposed between the surrounding wall 34 and the partitioning plate 42.

The partitioning plates 41, 42 and the heat dissipating fins 43, 44, 45 are made from a heat-conducting material.

During cooling operation, heat generated by the CPU 21 is conducted through the thermally conductive pad 5 and the fins 43, 44, 45 to the coolant passing through the tortuous channel in the housing 3, thereby removing the heat generated by the CPU 21.

With the inclusion of the fins 43, 44, 45 in the tortuous channel in the housing 3 of the heat dissipating unit 100 of the CPU cooling device of this invention, the heat dissipating efficiency can be considerably enhanced as compared to the aforesaid conventional heat dissipating unit.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A heat dissipating unit comprising:
a housing defining an inner space therein, a fluid inlet in fluid communication with said inner space and adapted to receive a coolant therein, and a fluid outlet in fluid communication with said inner space and adapted to discharge the coolant therefrom;
a plurality of partitioning plates disposed in said inner space so as to divide said inner space into a plurality of compartments that are connected to each other in an end-to-end manner such that said compartments cooperate to form a continuous tortuous channel with two ends respectively connected to said fluid inlet and said fluid outlet; and
a plurality of heat dissipating fins that are formed in each of said compartments.

2. The heat dissipating unit of claim 1, wherein said housing has upper and lower walls, each of said partitioning plates being transverse to and interconnecting said upper and lower walls, each of said heat dissipating fins being transverse to and interconnecting said upper and lower walls, each of said compartments being divided into a plurality of fluid passages by the respective ones of said heat dissipating fins disposed therein.

3. The heat dissipating unit of claim 2, wherein said housing further has a surrounding wall transverse to and interconnecting said upper and lower walls, and having two parallel first side wall portions, and two parallel second side wall portions interconnecting said first side wall portions, each of said heat dissipating fins being in the form of a thin plate, said partitioning plates and said heat dissipating fins being parallel to said first side wall portions, each of said partitioning plates extending from a respective one of said second side wall portions toward the other of said second side wall portions and having a connecting end and a free end opposite to said connecting end, said connecting ends of each two adjacent ones of said partitioning plates being respectively connected to said second side wall portions, each of said partitioning plates further having a free end section that extends from said free end toward said connecting end, said free end sections of each two adjacent ones of said partitioning plates being disposed to overlap each other.

4. A central processing unit (CPU) cooling device comprising:
a housing defining an inner space therein, a fluid inlet in fluid communication with said inner space and adapted to receive a coolant therein, and a fluid outlet in fluid communication with said inner space and adapted to discharge the coolant therefrom, said housing having a lower wall with a planar outer surface;
a plurality of partitioning plates disposed in said inner space so as to divide said inner space into a plurality of compartments that are connected to each other in an end-to-end manner such that said compartments cooperate to form a continuous tortuous channel with two ends respectively connected to said fluid inlet and said fluid outlet;
a thermally conductive pad bonded to said planar outer surface of said lower wall of said housing and adapted to be bonded to a central processing unit for conducting heat from the central processing unit to the coolant in said tortuous channel; and
a plurality of heat dissipating fins that are formed in each of said compartments.

5. The CPU cooling device of claim 4, wherein said housing further has an upper wall opposite to said lower wall, each of said partitioning plates being transverse to and interconnecting said upper and lower walls, each of said heat dissipating fins being transverse to and interconnecting said upper and lower walls, each of said compartments being divided into a plurality of fluid passages by the respective ones of said heat dissipating fins.

6. The CPU cooling device of claim 5, wherein said housing further has a surrounding wall transverse to and interconnecting said upper and lower walls, and having two parallel first side wall portions, and two parallel second side wall portions interconnecting said first side wall portions, each of said heat dissipating fins being in the form of a thin plate, said partitioning plates and said heat dissipating fins being parallel to said first side wall portions, each of said partitioning plates extending from a respective one of said second side wall portions toward the other of said second side wall portions and having a connecting end and a free end opposite to said connecting end, said connecting ends of each two adjacent ones of said partitioning plates being respectively connected to said second side wall portions, each of said partitioning plates further having a free end section that extends from said free end toward said connecting end, said free end sections of each two adjacent ones of said partitioning plates being disposed to overlap each other.

7. The CPU cooling device of claim 6, wherein said fluid inlet and said fluid outlet are formed in said upper wall.
